(19) United States
(12) Patent Application Publication
(10) Pub. No.: US 2025/0192517 A1
(43) Pub. Date: Jun. 12, 2025

(54) SEMICONDUCTOR DEVICE

(71) Applicant: Optoway Technology Inc., Hsin Chu (TW)

(72) Inventors: Meng-Lun Tsai, Taoyuan City (TW); Dawei Ren, Hsinchu County (TW); E-Min Chou, Hsinchu County (TW); Yu-Heng Jan, Hsinchu County (TW)

(73) Assignee: Optoway Technology Inc., Hsin Chu (TW)

(21) Appl. No.: 18/408,611

(22) Filed: Jan. 10, 2024

(30) Foreign Application Priority Data
Dec. 8, 2023 (TW) 112147976

(51) Int. Cl. H01S 5/12; H01S 5/026; H01S 5/042

(52) U.S. Cl. CPC H01S 5/12; H01S 5/0265; H01S 5/04256

(57) ABSTRACT

A semiconductor device including a semiconductor substrate, a first semiconductor stack layer, a plurality of grating structures and a plurality of DFB active waveguides is provided. The first semiconductor stack layer includes a first optical confinement layer, a first active layer and a second optical confinement layer sequentially disposed on the semiconductor substrate. The grating structures overlap the first semiconductor stack layer and define a grating area. The grating structures are arranged along a first direction and extend in a second direction. The DFB active waveguides overlap the grating structures. An included angle is provided between an extending direction of each of the DFB active waveguides and the first direction. The included angles of the DFB active waveguides are different.

### CROSS-REFERENCE TO RELATED APPLICATION

This application claims the priority benefit of Taiwan application serial no. 112147976, filed on Dec. 8, 2023. The entirety of the above-mentioned patent application is hereby incorporated by reference herein and made a part of this specification.

### BACKGROUND

### Technical Field

The disclosure relates to a semiconductor structure, and in particularly, relates to a semiconductor device.

### Description of Related Art

Semiconductor lasers have been widely used in fields such as optical communications and precision measurement due to the merits of small size, low power consumption, long life and low cost. Commonly used semiconductor lasers can be roughly divided into three major types: Fabry-Perot laser, distributed feedback (DFB) laser and vertical cavity surface emitting laser (VCSEL). Among them, DFB laser has become the mainstream light source in the field of optical communication due to its characteristics such as simple manufacturing process, narrow linewidth, single-longitudinal-mode output and long-distance transmission.

Since the DFB laser uses the grating structure design adjacent to the active layer to select a specific wavelength to generate feedback, the laser resonant cavity only allows light with a single wavelength to resonate, so as to form a single-frequency laser. To meet output requirements for multiple wavelengths, current solutions mostly rely on setting up multiple DFB lasers with different grating structures, which not only increases the complexity of optical path design and production costs, but also increases the difficulty of component miniaturization.

### SUMMARY

The disclosure provides a semiconductor device, the wavelength of laser beam generated by the semiconductor device is adjustable, and the integration of the semiconductor device is better.

The semiconductor device includes a semiconductor substrate, a first semiconductor stack layer, a plurality of grating structures and a plurality of DFB active waveguides. The first semiconductor stack layer includes a first optical confinement layer, a first active layer and a second optical confinement layer sequentially disposed on the semiconductor substrate. The grating structures overlap the first semiconductor stack layer and define a grating area. The grating structures are arranged along a first direction and extend in a second direction. The DFB active waveguides overlap the grating structures. An included angle is provided between an extending direction of each of the DFB active waveguides and the first direction. The included angles of the DFB active waveguides are different.

Based on the above, in the semiconductor device according to an embodiment of the disclosure, a plurality of grating structures and a plurality of DFB active waveguides overlapped with each other are provided. Since the included angle between the extending direction of each DFB active waveguide and the extending direction of the grating structures is different, the wavelengths of laser beam generated and transmitted in the DFB active waveguides may be different. Therefore, the wavelength of the laser beam output by the semiconductor device of the disclosure may be modulated, and the overall volume of the semiconductor device may be reduced.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top-view of a semiconductor device according to one embodiment of the disclosure.

FIG. 2 is a schematic cross-sectional view of the semiconductor device of FIG. 1.

FIG. 3 is a schematic top-view of a semiconductor device according to one embodiment of the disclosure.

FIG. 4 is a schematic cross-sectional view of the semiconductor device of FIG. 3.

FIG. 5 is a schematic cross-sectional view of a semiconductor device according to another embodiment of the disclosure.

FIG. 6 is a schematic top-view of a semiconductor device according to another embodiment of the disclosure.

FIG. 7 is a schematic cross-sectional view of the semiconductor device of FIG. 6.

FIG. 8 is a schematic top-view of a semiconductor device according to still another embodiment of the disclosure.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top”, “bottom”, “front”, “back”, etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including”, “comprising”, or “having” and variations thereof herein is meant to encompass the items listed thereafter and equivalents thereof as well as additional items. Unless limited otherwise, the terms “connected”, “coupled”, and “mounted” and variations thereof herein are used broadly and encompass direct and indirect connections, couplings, and mountings. Similarly, the terms “facing”, “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

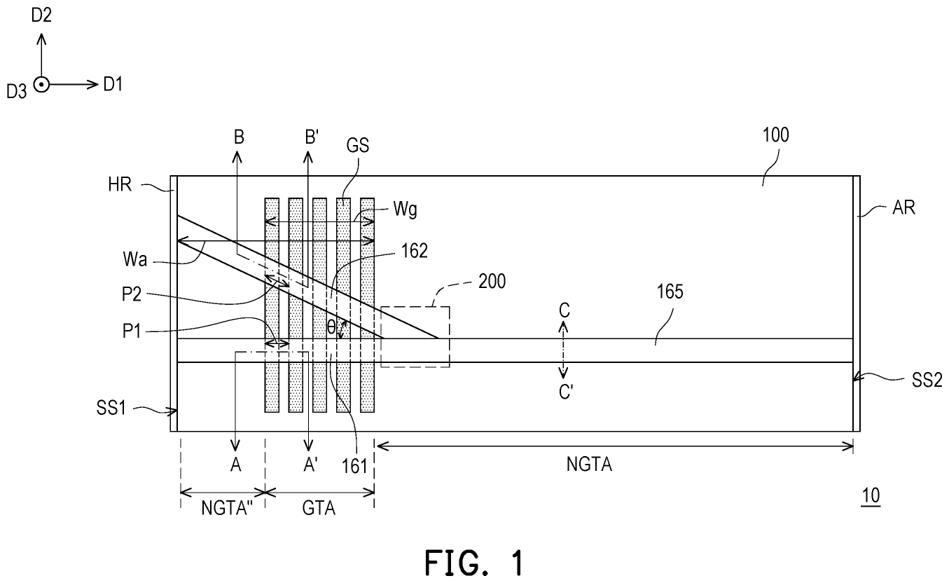

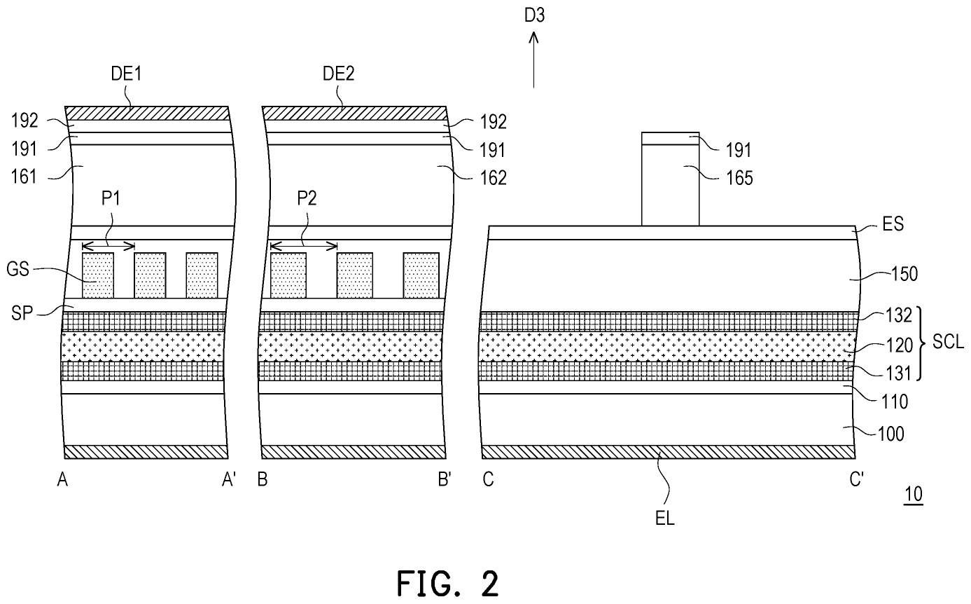

FIG. 1 is a schematic top-view of a semiconductor device according to one embodiment of the disclosure. FIG. 2 is a schematic cross-sectional view of the semiconductor device of FIG. 1. FIG. 2 corresponds to the section line A-A′, section line B-B′ and section line C-C″ in FIG. 1. For clarity, FIG. 1 only illustrates the semiconductor substrate 100, the first DFB active waveguide 161, the second DFB active waveguide 162 and the waveguide 165 in FIG. 2.

Referring to FIGS. 1 and 2, the semiconductor device 10 includes a semiconductor substrate 100, a semiconductor stack layer SCL (i.e., a first semiconductor stack layer), and a plurality of grating structures GS. The semiconductor stack layer SCL is disposed on the semiconductor substrate 100 and includes a first optical confinement layer 131, an active layer 120 (i.e., a first active layer), and a second optical confinement layer 132. The active layer 120 is disposed on the first optical confinement layer 131. The second optical confinement layer 132 is disposed on the active layer 120. That is, the active layer 120 is sandwiched between the first optical confinement layer 131 and the second optical confinement layer 132.

In the embodiment, the semiconductor substrate 100 is, for example, a N-type InP substrate, but the disclosure is not limited thereto. The active layer 120 is, for example, a multiple quantum well (MQW) layer, that is, the active layer 120 may be a stack structure of a plurality of quantum wells and a plurality of barrier layers alternately arranged, and its materials include, for example, In_{1-x-y}AlₓGa_{y}As or In₁₋ₓGaₓAs_{y}P_{1-y}, but the disclosure is not limited thereto. The first optical confinement layer 131 and the second optical confinement layer 132 may be separate confinement heterostructure (SCH) layers or graded-index separate confinement heterostructure (GRIN-SCH) layers, and their materials include, for example, In_{1-x-y}AlₓGa_{y}As or In₁₋ₓGaₓAs_{y}P_{1-y}, but the disclosure is not limited thereto. In the embodiment, a buffer layer 110 may be provided between the semiconductor stack layer SCL and the semiconductor substrate 100. The material of the buffer layer 110 is, for example, N-type InP, but the disclosure is not limited thereto.

The plurality of grating structures GS defining a grating area GTA are disposed on the semiconductor stack layer SCL, and overlap the semiconductor stack layer SCL. The overlapping relationship herein means, for example, that the grating structures GS and the semiconductor stack layer SCL overlap with each other along the direction D3. By the way, unless otherwise mentioned below, the overlapping relationship between two components will be defined in the same way, and the overlapping direction will not be described again.

In the embodiment, the plurality of grating structures GS may be arranged on the semiconductor stack layer SCL along the direction D1, and extend in the direction D2. The direction D1, the direction D2 and the direction D3 may be selectively perpendicular to each other. The grating structures GS may be produced using holographic lithography technology, photolithography technology, electron beam lithography technology, nanoimprint technology or integrated processes of the above. The material of the grating structures GS includes, for example, InGaAsP, but the disclosure is not limited thereto. In the embodiment, a spacer layer SP may also be provided between the grating structures GS and the semiconductor stack layer SCL, and its material includes, for example, InP, but the disclosure is not limited thereto.

For example, in the embodiment, the grating structures GS may be arranged at intervals along the direction D1 according to the arrangement period P1, and the arrangement period P1 may substantially satisfy the following relationship: P1=λ₁/(2n_{eff}), where λ₁ is one of the laser beam wavelengths to be output by the semiconductor device 10, and n_{eff} is the equivalent refractive index of the semiconductor waveguide. That is, the wavelength of the laser beam generated by the semiconductor device 10 is positively correlated with the arrangement period of the grating structures GS. It should be noted that the wavelength of laser beam mentioned here refers to the wavelength of laser beam in the semiconductor waveguide. In the embodiment, the semiconductor device 10 may further include a cladding layer 150 covering the plurality of grating structures GS, and the material of the cladding layer 150 includes, for example, InP, but the disclosure is not limited thereto.

Furthermore, the semiconductor device 10 further includes a first DFB active waveguide 161, a second DFB active waveguide 162 and a waveguide 165. The first DFB active waveguide 161 and the second DFB active waveguide 162 are disposed on the plurality of grating structures GS, and overlap the grating structures GS. The waveguide 165 is disposed in a non-grating area NGTA outside the grating area GTA. The material of the active waveguides includes, for example, P-type InP, but the disclosure is not limited thereto.

It is particularly noted that, in the embodiment, the extending direction of the first DFB active waveguide 161 may be selectively parallel to the arrangement direction (e.g., the direction D1) of the plurality of grating structures GS, that is, a included angle (i.e., a first included angle) between the extending direction of the first DFB active waveguide 161 and the arrangement direction of the grating structures GS is 0 degrees. The extending direction of the second DFB active waveguide 162 is neither parallel nor perpendicular to the arrangement direction of the plurality of grating structures GS, such as the included angle θ between the extending direction of the second DFB active waveguide 162 and the arrangement direction of the plurality of grating structures GS may be greater than 0 degrees and less than or equal to 45 degrees.

In the embodiment, the materials of the first DFB active waveguide 161 and the second DFB active waveguide 162 include, for example, P-type InP, but the disclosure is not limited thereto. In order to meet the requirements of the waveguide manufacturing process, an etching stop layer ES may be further provided on the cladding layer 150, and its material includes, for example, InGaAsP, but the disclosure is not limited thereto. On the other hand, the waveguide 165 is, for example, a passive waveguide, and its material may be the same as or different from the material of the active waveguide. In the embodiment, the materials of the waveguide 165 and the active waveguides may optionally be the same.

Specifically, in the embodiment, the materials of a part of the active layer 120 overlapping the first DFB active waveguide 161 and another part of the active layer 120 overlapping the second DFB active waveguide 162 may be selectively the same, but the disclosure is not limited thereto. In other embodiments, the active layer material overlapping the first DFB active waveguide 161 may be different from the active layer material overlapping the second DFB active waveguide 162, for example, using different gain media. Additionally, the different gain media may be photoluminescence (PL) materials with different excitation wavelengths.

Furthermore, the semiconductor device 10 may be provided with a coupler 200 in the non-grating area NGTA. The first DFB active waveguide 161 and the second DFB active waveguide 162 respectively extend from the grating area GTA to the non-grating area NGTA to couple one end of the coupler 200, and the other end of the coupler 200 is coupled to the waveguide 165. That is, the two DFB active waveguides may be coupled to the waveguide 165 via the coupler 200. In the embodiment, the coupler 200 is, for example, a low-loss coupler, but the disclosure is not limited thereto. The coupler 200 mentioned here may also be any coupler structure used for transmission and integration of optical signals that is familiar to those with ordinary knowledge in the technical field to which the present invention belongs. The present disclosure is not limited thereto, and therefore does not go into details.

In the embodiment, the semiconductor stack layer SCL has a first side surface SS1 and a second side surface SS2 opposite to each other, and the arrangement direction (e.g., direction D1) of the two side surfaces are perpendicular to the stacking direction (e.g., direction D3) of the semiconductor stack layer SCL. The plurality of grating structures GS, the first DFB active waveguide 161 and the second DFB active waveguide 162 are disposed on the semiconductor stack layer SCL and in an area closer to the first side surface SS1, that is, the grating area GTA is adjacent to the first side surface SS1 of the semiconductor stack layer SCL. The first DFB active waveguide 161 and the second DFB active waveguide 162 extend from the first side surface SS1, and the waveguide 165 coupled to the first DFB active waveguide 161 and the second DFB active waveguide 162 extends to the second side surface SS2.

More specifically, a width Wa between the first side surface SS1 and a side edge of the grating area GTA facing away from the first side surface SS1 is provided along the direction D1. The grating area GTA has a width Wg along the direction D1, and the ratio of the width Wg to the width Wa ranges from 0.2 to 1. In the embodiment, the ratio of the width Wg to the width Wa may be less than 1, that is, another non-grating area NGTA″ may be provided between the grating area GTA and the first side surface SS1. From another point of view, the grating area GTA only overlaps part of the first DFB active waveguide 161 and part of the second DFB active waveguide 162, while another part of the first DFB active waveguide 161 and another part of the second DFB active waveguide 162 extend in the non-grating area NGTA″.

For example, in the embodiment, the second side surface SS2 of the semiconductor stack layer SCL may serve as the light-emitting surface of the semiconductor device 10, so an anti-reflection layer AR may be provided on the second side surface SS2. A high reflective layer HR may be provided on the first side surface SS1 of the semiconductor stack layer SCL. The anti-reflection layer AR and the high reflective layer HR mentioned here may be any high reflective layer and anti-reflection layer commonly used in laser devices that are commonly used by those with ordinary skill in the technical field of the present invention. The present disclosure is not limited thereto, and therefore does not go into details.

The semiconductor device 10 further includes a first driving electrode DE1, a second driving electrode DE2 and an electrode layer EL that are electrically independent from each other. The first driving electrode DE1 and the second driving electrode DE2 are disposed on the first DFB active waveguide 161 and the second DFB active waveguide 162, and overlap the first DFB active waveguide 161 and the second DFB active waveguide 162 respectively. The electrode layer EL is disposed on a side of the semiconductor substrate 100 facing away from the semiconductor stack layer SCL. In the embodiment, a spacer layer 191 and a contact layer 192 may be further provided between the driving electrodes and the active waveguides. The material of the spacer layer 191 includes, for example, P-type InGaAsP, and the material of the contact layer 192 includes, for example, P-type InGaAs. However, the disclosure is not limited thereto. In some modified embodiments, at least one InGaAs layer may be further provided between the spacer layer 191 and the DFB active waveguides.

A first laser beam with a first wavelength is generated as a current is applied to the portion of the semiconductor stack layer SCL and the plurality of grating structures GS overlapping the first DFB active waveguide 161 (i.e., a DC voltage is applied between the first driving electrode DE1 and the electrode layer EL), and a second laser beam with a second wavelength is generated as a current is applied to another portion of the semiconductor stack SCL and the plurality of grating structures GS overlapping the second DFB active waveguide 162 (i.e., another DC voltage is applied between the second driving electrode DE2 and the electrode layer EL). That is, the semiconductor device 10 herein operates in a continuous wave (CW) mode.

However, the present disclosure is not limited thereto. An AC voltage may also be applied between the first driving electrode DE1 (or the second driving electrode DE2) and the electrode layer EL, so that the semiconductor device 10 outputs a modulated laser signal. That is, the semiconductor device 10 of the embodiment may also be used as a directly modulated laser (DML).

Since the included angle between the extending direction of the grating structures GS and the extending direction of each of the first DFB active waveguide 161 and the second DFB active waveguide 162 is different, the grating periods corresponding to the laser beams in the waveguides are also different. For example, the grating period (i.e., the arrangement period P1 of the grating structures GS along the extending direction of the first DFB active waveguide 161) corresponding to the laser beam confined in the first DFB active waveguide 161 is less than the grating period (i.e., an arrangement period P2 of the grating structures GS along the extending direction of the second DFB active waveguide 162) corresponding to the laser beam confined in the second DFB active waveguide 162. Therefore, the first wavelength λ₁ of the first laser beam generated in the first DFB active waveguide 161 is less than the second wavelength λ₂ of the second laser beam generated in the second DFB active waveguide 162. The first wavelength λ₁ and the second wavelength λ₂ herein respectively satisfies the following relationships: P1=λ₁/(2n_{eff}) and P2=λ₂/(2n_{eff}), where n_{eff} is the equivalent refractive index of the corresponding semiconductor waveguide (i.e., active waveguide).

In other words, the wavelength of laser beam output by the semiconductor device 10 of the embodiment may be modulated by driving the first driving electrode DE1 on the first DFB active waveguide 161 or the second driving electrode DE2 on the second DFB active waveguide 162 respectively. In addition, the grating structures GS overlapping the first DFB active waveguide 161 and the second DFB active waveguide 162 are the same, so the layout space of the semiconductor device 10 may be greatly reduced.

It should be noted that, although the semiconductor device 10 of the embodiment is a laser structure with a ridge waveguide, the invention is not limited thereto. In other embodiments, the aforementioned configuration relationship between the DFB active waveguides and the grating structures GS may also be applied to a laser device with a buried heterostructure or a high-mesa buried heterostructure.

Other embodiments will be enumerated below to describe the present invention in detail, in which the same components will be marked with the same symbols, and descriptions of the same technical content will be omitted. Please refer to the previous embodiments for the omitted parts, which will not be described again.

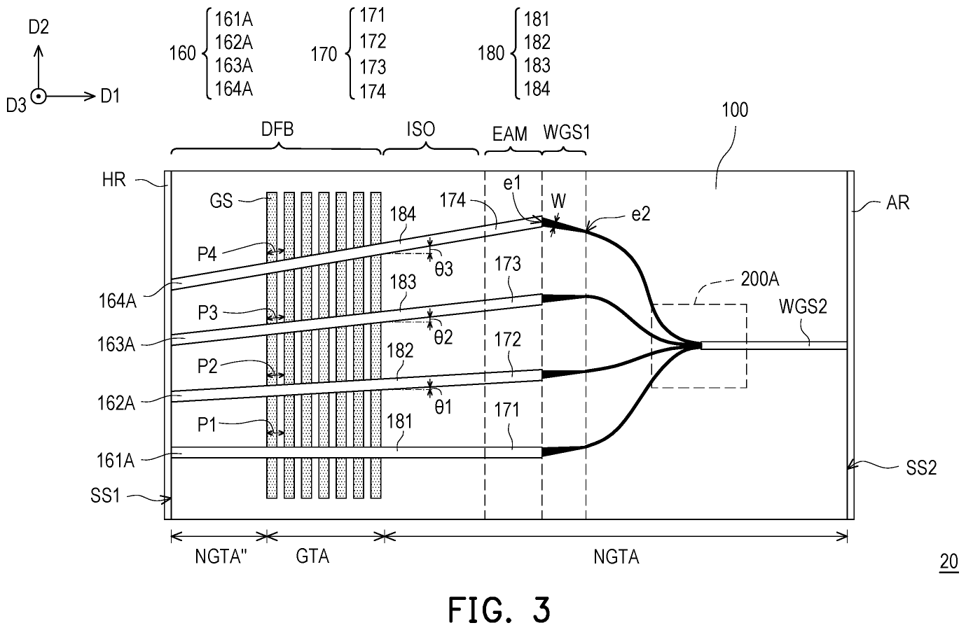

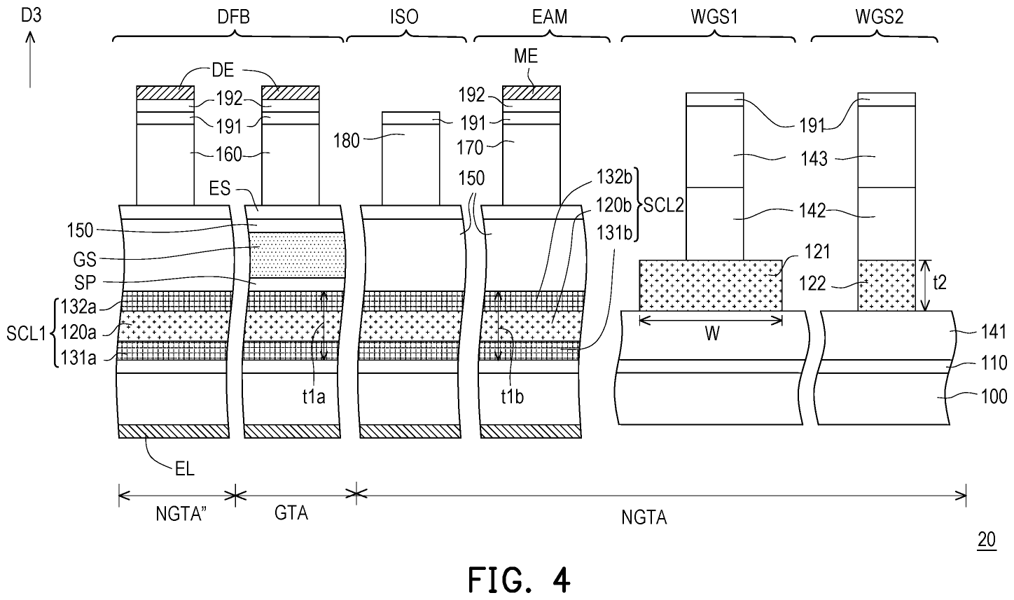

FIG. 3 is a schematic top-view of a semiconductor device according to one embodiment of the disclosure. FIG. 4 is a schematic cross-sectional view of the semiconductor device of FIG. 3. For clarity, FIG. 3 only illustrates the semiconductor substrate 100, a plurality of DFB active waveguides 160, a plurality of ISO waveguides 180, a plurality of EAM active waveguides 170, a plurality of first waveguide structures WGS1 and a second waveguide structure WGS2 in FIG. 4.

Referring to FIGS. 3 and 4, the semiconductor device 20 includes a semiconductor substrate 100 and a distributed feedback laser DFB. The distributed feedback laser DFB is disposed on the semiconductor substrate 100 and includes a first semiconductor stack layer SCL1, a plurality of grating structures GS and a plurality of DFB active waveguides 160. The first semiconductor stack layer SCL1 is disposed on the semiconductor substrate 100 and includes a first optical confinement layer 131a, a first active layer 120a and a second optical confinement layer 132a. The first active layer 120a is disposed on the first optical confinement layer 131a. The second optical confinement layer 132a is disposed on the first active layer 120a. That is, the first active layer 120a is sandwiched between the first optical confinement layer 131a and the second optical confinement layer 132a.

In the embodiment, the semiconductor substrate 100 is, for example, an N-type InP substrate, but the disclosure is not limited thereto. The first active layer 120a is, for example, a multiple quantum well (MQW) layer, that is, the first active layer 120a may be a stack structure of a plurality of quantum wells and a plurality of barrier layers alternately arranged, and its materials include, for example, In_{1-x-y}AlₓGa_{y}As or In₁₋ₓGaₓAs_{y}P_{1-y}, but the disclosure is not limited thereto. The first optical confinement layer 131a and the second optical confinement layer 132a may be separate confinement heterostructure (SCH) layers or graded-index separate confinement heterostructure (GRIN-SCH) layers, and their materials include, for example, In_{1-x-y}AlₓGa_{y}As or In₁₋ₓGaₓAs_{y}P_{1-y}, but the disclosure is not limited thereto. In the embodiment, a buffer layer 110 may be provided between the first semiconductor stack layer SCL1 and the semiconductor substrate 100. The material of the buffer layer 110 is, for example, N-type InP, but the disclosure is not limited thereto.

The plurality of grating structures GS defining a grating area GTA are disposed on the first semiconductor stack layer SCL1 and overlap the first semiconductor stack layer SCL1. In the embodiment, the plurality of grating structures GS may be arranged on the first semiconductor stack layer SCL1 along the direction D1, and extend in the direction D2, but the disclosure is not limited thereto. In other embodiments, the grating structures GS may also be disposed between the first semiconductor stack layer SCL1 and the semiconductor substrate 100, that is, the first semiconductor stack layer SCL1 may be disposed above the plurality of grating structures GS. The grating structures GS may be produced using holographic lithography technology, photolithography technology, electron beam lithography technology or integrated processes of the above. The material of the grating structures GS includes, for example, InGaAsP, but the disclosure is not limited thereto. In the embodiment, a spacer layer SP may also be provided between the grating structures GS and the first semiconductor stack layer SCL1, and its material includes, for example, InP, but the disclosure is not limited thereto.

For example, in the embodiment, the grating structures GS may be arranged at intervals along the direction D1 according to the arrangement period P1, and the arrangement period P1 may substantially satisfy the following relationship: P1=λ₁/(2n_{eff}), where λ₁ is one of the laser beam wavelengths to be output by the distributed feedback laser DFB, and n_{eff} is the equivalent refractive index of the semiconductor waveguide. That is, the wavelength of the laser beam generated by the distributed feedback laser DFB is positively correlated with the arrangement period of the grating structures GS. It should be noted that the wavelength of laser beam mentioned herein refers to the wavelength of laser beam in the semiconductor waveguide. In the embodiment, the distributed feedback laser DFB may further include a cladding layer 150 covering the plurality of grating structures GS, and the material of the cladding layer 150 includes, for example, InP, but the disclosure is not limited thereto.

In the embodiment, the distributed feedback laser DFB may be provided with four DFB active waveguides 160, which are a first DFB active waveguide 161A, a second DFB active waveguide 162A, a third DFB active waveguide 163A and a fourth DFB active waveguide 164A. The four DFB active waveguides 160 are disposed on the grating structures GS and overlap the grating structures GS. The material of the DFB active waveguide 160 includes, for example, P-type InP, but the disclosure is not limited thereto.

It is particularly noted that, in the embodiment, the extending direction of the first DFB active waveguide 161A may be selectively parallel to the arrangement direction (e.g., the direction D1) of the plurality of grating structures GS, that is, an included angle (i.e., a first included angle) between the extending direction of the first DFB active waveguide 161A and the arrangement direction of the grating structures GS is 0 degrees. The extending direction of each of the second DFB active waveguide 162A, the third DFB active waveguide 163A and the fourth DFB active waveguide 164A is neither parallel nor perpendicular to the arrangement direction of the plurality of grating structures GS.

For example, an included angle θ1 between the extending direction of the second DFB active waveguide 162A and the arrangement direction of the plurality of grating structures GS, an included angle θ2 between the extending direction of the third DFB active waveguide 163A and the arrangement direction of the plurality of grating structures GS, and an included angle θ3 between the extending direction of the fourth DFB active waveguide 164A and the arrangement direction of the plurality of grating structures GS may be greater than 0 degrees and less than or equal to 45 degrees. In the embodiment, the included angle θ3 may be greater than the included angle θ2, and the included angle θ2 may be greater than the included angle θ1.

In the embodiment, the materials of the first DFB active waveguide 161A, the second DFB active waveguide 162A, the third DFB active waveguide 163A and the fourth DFB active waveguide 164A include, for example, P-type InP, but the disclosure is not limited thereto. In order to meet the requirements of the waveguide manufacturing process, an etching stop layer ES may be further provided on the cladding layer 150, and its material includes, for example, InGaAs P, but the disclosure is not limited thereto.

Specifically, in the embodiment, the materials of four parts of the first active layer 120a overlapping the four DFB active waveguides 160 may be selectively the same, but the disclosure is not limited thereto. In other embodiments, the materials of the first active layers overlapping the plurality of DFB active waveguides 160 may be different, for example, different gain media may be selected. Additionally, the different gain media may be photoluminescence (PL) materials with different excitation wavelengths.

The distributed feedback laser DFB further includes a plurality of driving electrodes DE and an electrode layer EL that are electrically independent of each other. The driving electrodes DE are respectively disposed on and overlap with the plurality of DFB active waveguides 160. The electrode layer EL is disposed on a side of the semiconductor substrate 100 facing away from the first semiconductor stack layer SCL1 and overlaps the first semiconductor stack layer SCL1. In the embodiment, a spacer layer 191 and a contact layer 192 may be further provided between the driving electrode DE and the DFB active waveguide 160. The material of the spacer layer 191 includes, for example, P-type InGaAsP, and the material of the contact layer 192, for example, includes P-type InGaAs, but the disclosure is not limited thereto.

A first laser beam with a first wavelength is generated as a current is applied to the first portion of the first semiconductor stack layer SCL1 and the plurality of grating structures GS overlapping the first DFB active waveguide 161A. A second laser beam with a second wavelength is generated as a current is applied to the second portion of the first semiconductor stack layer SCL1 and the plurality of grating structures GS overlapping the second DFB active waveguide 162A. A third laser beam with a third wavelength is generated as a current is applied to the third portion of the first semiconductor stack layer SCL1 and the plurality of grating structures GS overlapping the third DFB active waveguide 163A. A fourth laser beam with a fourth wavelength is generated as a current is applied to the fourth portion of the first semiconductor stack SCL1 and the plurality of grating structures GS overlapping the fourth DFB active waveguide 164A.

Since the included angle between the extending direction of the grating structure GS and the extending direction of each of the first DFB active waveguide 161A, the second DFB active waveguide 162A, the third DFB active waveguide 163A and the fourth DFB active waveguide 164A is different, the grating periods corresponding to the laser beams in the waveguides are also different.

For example, the grating period (i.e., the arrangement period P1 of the grating structures GS along the extending direction of the first DFB active waveguide 161A) corresponding to the laser beam confined in the first DFB active waveguide 161A is less than the grating period (i.e., an arrangement period P2 of the grating structures GS along the extending direction of the second DFB active waveguide 162A) corresponding to the laser beam confined in the second DFB active waveguide 162A. The grating period (i.e., the arrangement period P2) corresponding to the laser beam confined in the second DFB active waveguide 162A is less than the grating period (i.e., an arrangement period P3 of the grating structures GS along the extending direction of the third DFB active waveguide 163A) corresponding to the laser beam confined in the third DFB active waveguide 163A. The grating period (i.e., the arrangement period P3) corresponding to the laser light beam confined in the third DFB active waveguide 163A is less than the grating period (i.e., an arrangement period P4 of the grating structures GS along the extending direction of the fourth DFB active waveguide 164A) corresponding to the laser beam confined in the fourth DFB active waveguide 164A.

Based on the above, the wavelengths of the laser beams generated by the DFB active waveguides 160 are sorted from small to large, which are a first wavelength λ₁ of the first laser beam formed in the first DFB active waveguide 161A, a second wavelength λ₂ of the second laser beam formed in the second DFB active waveguide 162A, a third wavelength λ₃ of the third laser beam formed in the third DFB active waveguide 163A, and a fourth wavelength λ₄ of the fourth laser beam formed in the fourth DFB active waveguide 164A. The first wavelength λ₁, the second wavelength λ₂, the third wavelength λ₃ and the fourth wavelength λ₄ herein respectively satisfy the following relationships: P1=λ₁/(2n_{eff}), P2=λ₂/(2n_{eff}), P3=λ₃/(2n_{eff}) and P4=λ₄/(2n_{eff}), where n_{eff} is the equivalent refractive index of the semiconductor waveguide (i.e., active waveguide).

In the embodiment, the distributed feedback laser DFB may perform multi-wavelength laser output by driving the driving electrodes DE on the first DFB active waveguide 161A, the second DFB active waveguide 162A, the third DFB active waveguide 163A and the fourth DFB active waveguide 164A. In addition, the grating structures GS overlapping the four DFB active waveguides 160 are the same, so the layout space of the distributed feedback laser DFB may be greatly reduced.

It should be particularly noted that, in the embodiment, the first semiconductor stack layer SCL1 and the plurality of DFB active waveguides 160 of the distributed feedback laser DFB may extend from the grating area GTA to a non-grating area NGTA″ outside the grating area GTA. The non-grating area NGTA″ is located between a first side surface SS1 of the first semiconductor stack layer SCL1 and the grating area GTA. That is, the grating area GTA only overlaps a part of each DFB active waveguide 160, but the disclosure is not limited thereto. In other embodiments, the grating area may overlap the entirety of each DFB active waveguide 160, that is, the grating area may extend to the first side surface SS1 of the first semiconductor stack layer SCL1.

Furthermore, the semiconductor device 20 further includes a electro-absorption modulator EAM disposed on the semiconductor substrate 100 and located in the non-grating area NGTA outside the grating area GTA. The electro-absorption modulator EAM is coupled to the plurality of DFB active waveguides 160 of the distributed feedback laser DFB, and each includes a second semiconductor stack layer SCL2 and an EAM active waveguide 170.

The second semiconductor stack layer SCL2 is disposed on the semiconductor substrate 100 and includes a third optical confinement layer 131b, a second active layer 120b and a fourth optical confinement layer 132b. The second active layer 120b is disposed on the third optical confinement layer 131b. The fourth optical confinement layer 132b is disposed on the second active layer 120b. That is, the second active layer 120b is sandwiched between the third optical confinement layer 131b and the fourth optical confinement layer 132b.

In the embodiment, the materials of each film layer of the second semiconductor stack layer SCL2 and the first semiconductor stack layer SCL1 may be selectively the same. That is, the materials of the third optical confinement layer 131b, the second active layer 120b and the fourth optical confinement layer 132b may be the same as the materials of the first optical confinement layer 131a, the first active layer 120a and the second optical confinement layer 132a respectively, but the disclosure is not limited thereto. In other embodiments, the film materials of the first semiconductor stack layer SCL1 and the second semiconductor stack layer SCL2 may be different.

Specifically, in a preferred embodiment, the film materials of a plurality of portions of the first semiconductor stack layer SCL1 overlapping the plurality of DFB active waveguides 160 may be different, and the film materials of a plurality of portions of the second semiconductor stack layer SCL2 overlapping the plurality of EAM active waveguides 170 may be different. For example, four portions of the first active layer 120a of the first semiconductor stack layer SCL1 overlapping the four DFB active waveguides 160 and four portions of the second active layer 120b of the second semiconductor stack layer SCL2 overlapping the four EAM active waveguide 170 may be made of eight photoluminescent materials (or gain media) with different excitation wavelengths.

On the other hand, the plurality of EAM active waveguides 170 are disposed on the second semiconductor stack layer SCL2 and are respectively coupled to the plurality of DFB active waveguides 160 of the distributed feedback laser DFB. It is particularly important to note that the extending directions of the EAM active waveguides 170 are different. In other words, the included angle between the extending direction of each of the EAM active waveguides 170 and the extending directions of the grating structures GS is different.

For example, in the embodiment, the electro-absorption modulator EAM may be provided with four EAM active waveguides 170, which are a first EAM active waveguide 171, a second EAM active waveguide 172, a third EAM active waveguide 172 and a fourth EAM active waveguide 174. The extending directions of the first EAM active waveguide 171, the second EAM active waveguide 172, the third EAM active waveguide 173 and the fourth EAM active waveguide 174 of the electro-absorption modulator EAM may be the same as the extending directions of the first DFB active waveguide 161A, the second DFB active waveguide 162A, the third DFB active waveguide 163A and the fourth DFB active waveguide 164A of the distributed feedback laser DFB, respectively.

The electro-absorption modulator EAM further includes a plurality of modulation electrodes ME and an electrode layer EL that are electrically independent of each other. The modulation electrodes ME are respectively disposed on and overlap the plurality of EAM active waveguides 170. The electrode layer EL is disposed on a side of the semiconductor substrate 100 facing away from the second semiconductor stack layer SCL2 and overlaps the second semiconductor stack layer SCL2. In the embodiment, a spacer layer 191 and a contact layer 192 may be further provided between the modulation electrodes ME and the EAM active waveguides 170. The material of the spacer layer 191 includes, for example, P-type InGaAsP, and the material of the contact layer 192, for example, includes P type InGaAs, but the disclosure is not limited thereto.

Specifically, in the embodiment, the semiconductor device 20 adopts a multi-wavelength laser output mode, that is, the plurality of driving electrodes DE on the plurality of DFB active waveguides 160 are driven simultaneously. Correspondingly, the electro-absorption modulator EAM also modulates multiple wavelengths of laser output by simultaneously driving the modulation electrodes ME on the EAM active waveguides 170.

From another point of view, except that the electro-absorption modulator EAM of present embodiment is not provided with a grating structure GS, the rest of the stacked structure is similar to the stacked structure of the distributed feedback laser DFB.

In order to ensure that the distributed feedback laser DFB and the electro-absorption modulator EAM are electrically independent of each other, four ISO waveguides 180 are provided between the distributed feedback laser DFB and the electro-absorption modulator EAM. The four ISO waveguides 180 are a first ISO waveguide 181, a second ISO waveguide 182, a third ISO waveguide 183 and a fourth ISO waveguide 184. The four ISO waveguides 180 are arranged in the non-grating area NGTA. The material of the ISO waveguide 180 includes, for example, P-type InP, but the disclosure is not limited thereto.

For example, the first ISO waveguide 181 connects the first DFB active waveguide 161A and the first EAM active waveguide 171. The second ISO waveguide 182 connects the second DFB active waveguide 162A and the second EAM active waveguide 172. The third ISO waveguide 183 connects the third DFB active waveguide 163A and the third EAM active waveguide 173. The fourth ISO waveguide 184 connects the fourth DFB active waveguide 164A and the fourth EAM active waveguide 174.

In the embodiment, the semiconductor device 20 further includes a plurality of first waveguide structures WGS1, a second waveguide structure WGS2 and a coupler 200A disposed on the semiconductor substrate 100. Each of the first waveguide structures WGS1 has a first end e1 and a second end e2 opposite to each other, and the plurality of first ends e1 of the first waveguide structures WGS1 are coupled to the electro-absorption modulator EAM. The coupler 200A disposed in the non-grating area NGTA is coupled to the plurality of second ends e2 of the first waveguide structures WGS1 and the second waveguide structure WGS2. More specifically, the first waveguide structures WGS1 are coupled to the second waveguide structure WGS2 via the coupler 200A. The coupler 200A is, for example, a multimode interference (MMI) coupler, but the disclosure is not limited thereto.

In the embodiment, the first waveguide structure WGS1 includes a first-type semiconductor layer 141, a first bulk semiconductor layer 121 and a second-type semiconductor layer 142. The first bulk semiconductor layer 121 is disposed on the first-type semiconductor layer 141. The second-type semiconductor layer 142 is disposed on the first bulk semiconductor layer 121. The first waveguide structure WGS1 may be further provided with a third-type semiconductor layer 143 and a spacer layer 191 on the second-type semiconductor layer 142, but the disclosure is not limited thereto.

Similarly, the second waveguide structure WGS2 includes a first-type semiconductor layer 141, a second bulk semiconductor layer 122 and a second-type semiconductor layer 142. The second bulk semiconductor layer 122 is disposed on the first-type semiconductor layer 141. The second-type semiconductor layer 142 is disposed on the second bulk semiconductor layer 122. The second waveguide structure WGS2 may be further provided with a third-type semiconductor layer 143 and a spacer layer 191 on the second-type semiconductor layer 142, but the disclosure is not limited thereto.

It should be noted that a film thickness t2 of each of the first bulk semiconductor layer 121 and the second bulk semiconductor layer 122 is significantly greater than a film thickness t1a of the first semiconductor stack layer SCL1 of the distributed feedback laser DFB and a film thickness t1b of the second semiconductor stack layer SCL2 of the electro-absorption modulator EAM. For example, the film thickness t2 of the bulk semiconductor layer may be in the range of 0.2 micrometers to 1.5 micrometers, the film thickness t1a of the first semiconductor stack layer SCL1 may be in the range of 50 nanometers to 500 nanometers, and the film thickness t1b of the second semiconductor stack layer SCL2 may be in the range of 100 nanometers to 1000 nanometers. On the other hand, the materials of the first bulk semiconductor layer 121 and the second bulk semiconductor layer 122 may be selectively the same, including, for example, InGaAsP, but the disclosure is not limited thereto. The materials of the first-type semiconductor layer 141 and the second-type semiconductor layer 142 include, for example, InP. The material of the third-type semiconductor layer 143 includes, for example, P-type InP, but the disclosure is not limited thereto.

In the embodiment, a width W of the first bulk semiconductor layer 121 of the first waveguide structure WGS1 decreases from the first end e1 (i.e., the end coupled to the DFB active waveguide 160) to the second end e2 (i.e., the other end coupled to the coupler 200A). More specifically, the first waveguide structure WGS1 of present embodiment may be a tapered waveguide structure, or other structural design suitable for mode matching. Therefore, the laser beams generated by the distributed feedback laser DFB may be transmitted to the coupler 200A through the first waveguide structures WGS1 with lower energy loss.

Furthermore, the semiconductor device 20 has a first side surface SS1 close to the grating structures GS and a second side surface SS2 far away from the grating structures GS and facing away from the first side surface SS1, and the arrangement direction (e.g., the direction D1) of these two side surfaces is perpendicular to a stacking direction (e.g., the direction D3) of the semiconductor stack layer. The DFB active waveguides 160 extend from the first side surface SS1, and the second waveguide structure WGS2 coupled to the coupler 200A extends to the second side surface SS2.

In the embodiment, the second side surface SS2 of the semiconductor device 20 may serve as the light-emitting surface of the laser beam generated by the distributed feedback laser DFB, so an anti-reflection layer AR may be provided on the second side surface SS2. A high reflective layer HR may be provided on the first side surface SS1 of the semiconductor device 20. The anti-reflection layer AR and the high-reflection layer HR mentioned here may be any high-reflection layer and anti-reflection layer commonly used in laser devices that are commonly used by those with ordinary skill in the technical field of the present invention. The present disclosure is not limited thereto, and therefore does not go into details.

In particular, multiple laser beams with different wavelengths generated in the plurality of DFB active waveguides 160 of the distributed feedback laser DFB may be output to the light-emitting surface (i.e., the second side surface SS2) of the semiconductor device 20 through the MMI coupler (i.e., the coupler 200A). Integrating the distributed feedback laser DFB, the electro-absorption modulator EAM and the coupler 200A on the same semiconductor substrate 100 may not only meet the high bandwidth requirements of signal transmission, but also effectively reduce the volume of the semiconductor device 20.

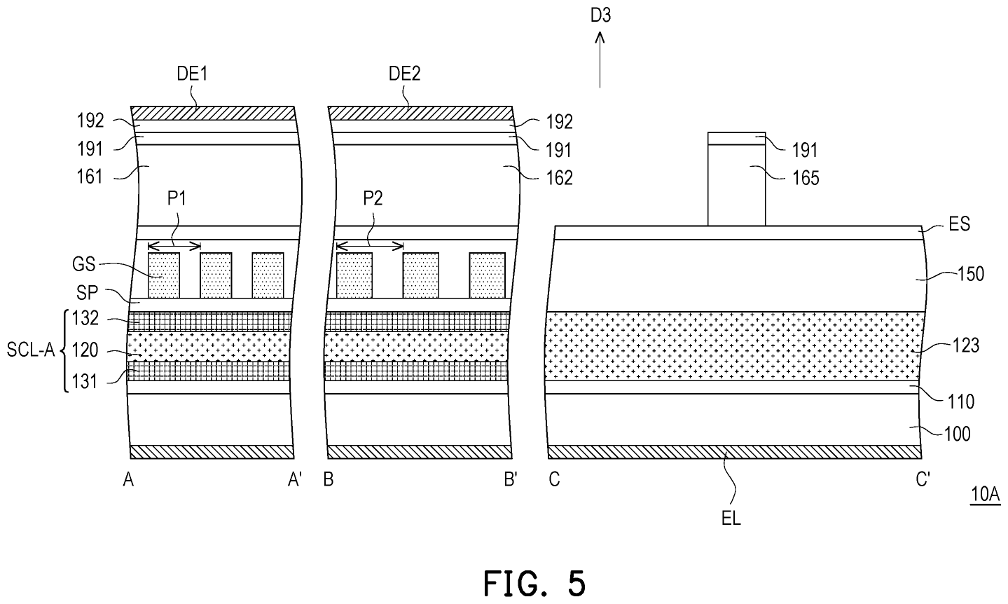

FIG. 5 is a schematic cross-sectional view of a semiconductor device according to another embodiment of the disclosure. Referring to FIG. 5, the difference between the semiconductor device 10A of present embodiment and the semiconductor device 10 of FIG. 2 lies in the arrangement of the semiconductor stack layer. For example, in the embodiment, the semiconductor stack layer SCL-A does not extend to a position overlapping the waveguide 165. In the area where the waveguide 165 is provided, a third bulk semiconductor layer 123 is provided between the buffer layer 110 and the cladding layer 150. The material of the third bulk semiconductor layer 123 includes, for example, InGaAsP, but the disclosure is not limited thereto.

Through the arrangement of the third bulk semiconductor layer 123, in addition to achieving the benefit of laser beam pattern matching, it may also prevent the semiconductor stack layer in the area where the passive waveguide (e.g., the waveguide 165) is arranged from being damaged due to excessive laser power, resulting in a reduction of the overall reliability of distributed feedback laser devices.

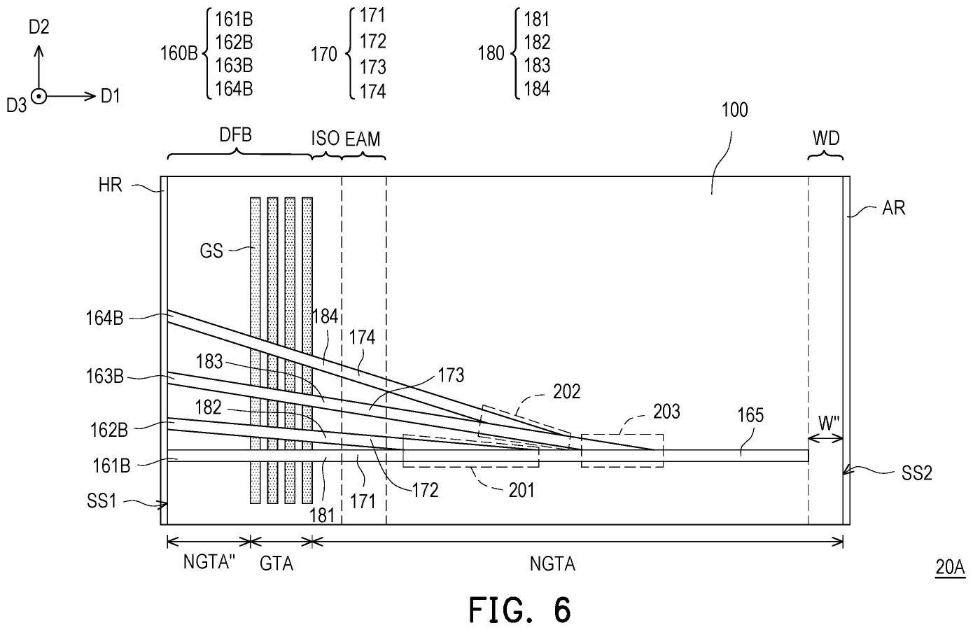

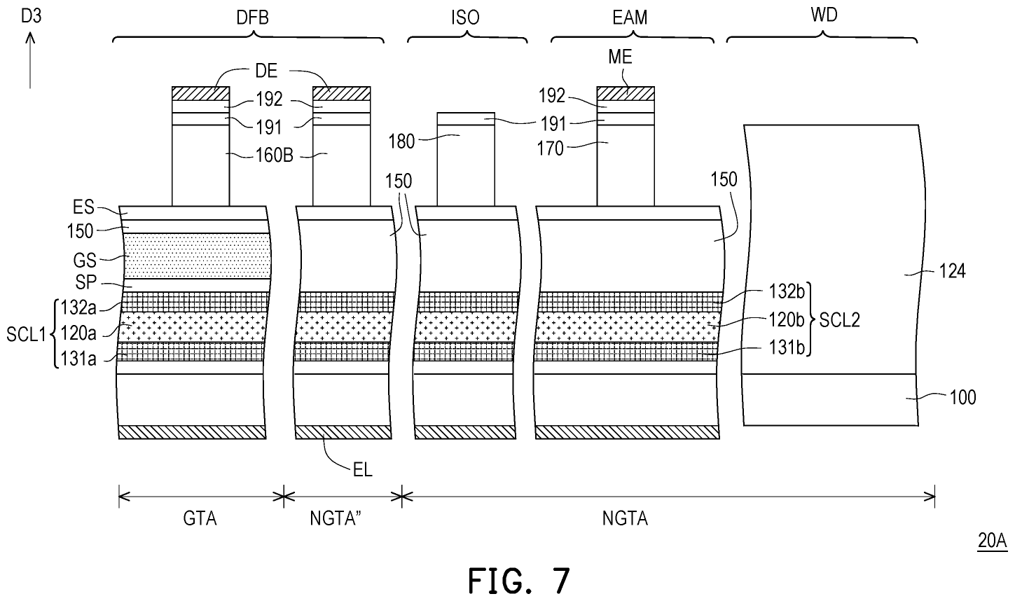

FIG. 6 is a schematic top-view of a semiconductor device according to another embodiment of the disclosure. FIG. 7 is a schematic cross-sectional view of the semiconductor device of FIG. 6. For clarity, FIG. 6 only illustrates the semiconductor substrate 100, a plurality of DFB active waveguides 160B, a plurality of EAM active waveguides 170, a plurality of ISO waveguides 180 and a plurality of grating structures GS in FIG. 7. Referring to FIGS. 6 and 7, the main difference between the semiconductor device 20A of present embodiment and the semiconductor device 20 of FIG. 3 lies in that the coupling mode between multiple active waveguides is different.

In the embodiment, the plurality of DFB active waveguides 160B may be coupled to the waveguide 165 via multiple low-loss couplers. For example, the first DFB active waveguide 161B and the second DFB active waveguide 162B may be coupled to the waveguide 165 via the coupler 201, and the third DFB active waveguide 163B and the fourth DFB active waveguide 164B may be coupled to the waveguide 165 via the coupler 202 and coupler 203.

Although the tilt direction of part of the DFB active waveguides 160B of present embodiment relative to the grating structures GS is different from the tilt direction of part of the DFB active waveguides 160 in FIG. 3 relative to the grating structures GS, the remaining configuration relationships (For example: distribution of the included angle between the extending direction of each of the DFB active waveguides and the extending direction of the grating structures GS, the configuration relationship between the ISO waveguides 180 and the EAM active waveguides 170) are all similar to the semiconductor device 20 in FIG. 3. Therefore, please refer to the relevant paragraphs of the foregoing embodiments for detailed description, which will not be repeated here.

It should be noted that, on the side adjacent to the anti-reflection layer AR, the semiconductor device 20A is further provided with a window structure WD connecting the waveguide 165 and the anti-reflection layer AR, and the window structure WD is, for example, a bulk semiconductor layer 124 directly disposed on the semiconductor substrate 100. The material of the bulk semiconductor layer 124 includes, for example, InP. Preferably, a width W″ of the window structure WD along the direction D1 may be in the range of 5 micrometers to 50 micrometers. Through the configuration of the window structure WD, the anti-reflection capability of the semiconductor device 20A on the side of the anti-reflection layer AR may be further improved.

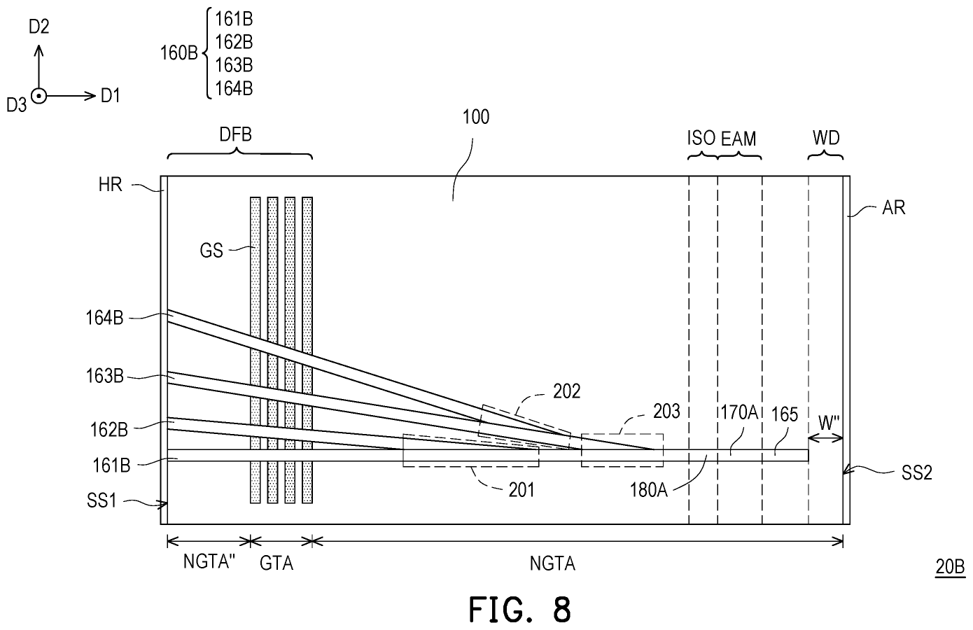

FIG. 8 is a schematic top-view of a semiconductor device according to still another embodiment of the disclosure. Referring to FIG. 8, the difference between the semiconductor device 20B of present embodiment and the semiconductor device 20A of FIG. 6 only lies in that the configurations of the ISO waveguide and the EAM active waveguide are different. For example, in the embodiment, the EAM active waveguide 170A and the ISO waveguide 180A of the semiconductor device 20B may be disposed on a side of the coupler 203 facing away from the distributed feedback laser DFB. That is, the distributed feedback laser DFB and the electro-absorption modulator EAM are respectively located on two opposite sides of the coupler 203 along the direction D1.

More specifically, the EAM active waveguide 170A and the ISO waveguide 180A may be disposed between the waveguide 165 and the coupler 203. The active waveguide 170A connects the waveguide 165 and the ISO waveguide 180A, and the ISO waveguide 180A connects the coupler 203. That is, in the embodiment, the number of each of the EAM active waveguide 170A and the ISO waveguide 180A may be one, but the disclosure is not limited thereto.

Since the composition structures of the EAM active waveguide 170A and the ISO waveguide 180A of present embodiment are similar to that of the EAM active waveguide 170 and the ISO waveguide 180 in FIG. 6, please refer to the relevant paragraphs of the foregoing embodiment for detailed description, which will not be repeated here.

In summary, in the semiconductor device according to an embodiment of the disclosure, a plurality of grating structures and a plurality of DFB active waveguides overlapped with each other are provided. Since the included angle between the extending direction of each DFB active waveguide and the extending direction of the grating structures is different, the wavelengths of laser beam generated and transmitted in the DFB active waveguides may be different. Therefore, the wavelength of the laser beam output by the semiconductor device of the disclosure may be modulated, and the overall volume of the semiconductor device may be reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a semiconductor substrate;
a first semiconductor stack layer, disposed on the semiconductor substrate, and comprising:
a first optical confinement layer;
a first active layer, disposed on the first optical confinement layer; and
a second optical confinement layer, disposed on the first active layer;
a plurality of grating structures, overlapping the first semiconductor stack layer, and defining a grating area, wherein the grating structures are arranged along a first direction and extend in a second direction; and
a plurality of DFB active waveguides, overlapping the grating structures, wherein an included angle is provided between an extending direction of each of the DFB active waveguides and the first direction, and the included angles of the DFB active waveguides are different.

2. The semiconductor device according to claim 1, wherein the extending direction of at least one of the DFB active waveguides is not perpendicular to the second direction.

3. The semiconductor device according to claim 1, further comprising:
a plurality of driving electrodes, disposed on the DFB active waveguides, and respectively overlapping the DFB active waveguides, wherein the driving electrodes are electrically independent from each other; and
an electrode layer, disposed on a side of the semiconductor substrate facing away from the first semiconductor stack layer, and overlapping the first semiconductor stack layer.

4. The semiconductor device according to claim 1, wherein gain media of at least two portions of the first active layer overlapping at least two of the DFB active waveguides are different.

5. The semiconductor device according to claim 1, further comprising:
a waveguide, disposed on the semiconductor substrate, and located in a non-grating area outside the grating area; and
a coupler, disposed in the non-grating area, and coupled to the DFB active waveguides and the waveguide.

6. The semiconductor device according to claim 1, wherein the DFB active waveguides include a first DFB active waveguide and a second DFB active waveguide, the first semiconductor stack layer, the grating structures and the first DFB active waveguide is adapted to generate a first laser beam with a first wavelength, the first semiconductor stack layer, the grating structures and the second DFB active waveguide is adapted to generate a second laser beam with a second wavelength, and the first wavelength is different from the second wavelength.

7. The semiconductor device according to claim 1, further comprising:
an electro-absorption modulator, disposed on the semiconductor substrate, and located in a non-grating area outside the grating area, wherein the electro-absorption modulator is coupled to the DFB active waveguides, and includes:
a second semiconductor stack layer, comprises:
a third optical confinement layer;
a second active layer, disposed on the third optical confinement layer; and
a fourth optical confinement layer, disposed on the second active layer;
at least one EAM active waveguide, disposed on the second semiconductor stack layer, and coupled to the DFB active waveguides;
at least one modulation electrode, disposed on the at least one EAM active waveguide, and overlapping the at least one EAM active waveguide; and
an electrode layer, disposed on a side of the semiconductor substrate facing away from the second semiconductor stack layer, and overlapping the second semiconductor stack layer.

8. The semiconductor device according to claim 7, wherein the at least one EAM active waveguide is a plurality of EAM active waveguides, the at least one modulation electrode is a plurality of modulation electrodes, the EAM active waveguides are respectively coupled to the DFB active waveguides, an included angle is provided between an extending direction of each of the EAM active waveguides and the second direction, the included angles of the EAM active waveguides are different, and the modulation electrodes respectively overlap the EAM active waveguides, and are electrically independent from each other.

9. The semiconductor device according to claim 8, further comprising:
a plurality of first waveguide structures, disposed on the semiconductor substrate, and each having a first end and a second end opposite to each other, wherein the first ends of the first waveguide structures are coupled to the electro-absorption modulator, each of the first waveguide structures includes:
a first-type semiconductor layer;
a first bulk semiconductor layer, disposed on the first-type semiconductor layer, wherein a width of the first bulk semiconductor layer decreases from the first end to the second end; and
a second-type semiconductor layer, disposed on the first bulk semiconductor layer.

10. The semiconductor device according to claim 9, further comprising:
a second waveguide structure, disposed on the semiconductor substrate, and comprising:
the first-type semiconductor layer;
a second bulk semiconductor layer, disposed on the first-type semiconductor layer; and
the second-type semiconductor layer, disposed on the second bulk semiconductor layer; and
a coupler, disposed in the non-grating area, and coupled to the second ends of the first waveguide structures and the second waveguide structure.
